(19) United States
(12) Patent Application Publication
(10) Pub. No.: US 2026/0077580 A1
(43) Pub. Date: Mar. 19, 2026

(54) SEPARATION SYSTEM AND SEPARATION METHOD

(71) Applicant: Kioxia Corporation, Minato-ku, Tokyo (JP)

(72) Inventors: Ai MORI, Yokkaichi Mie (JP); Hiroaki ASHIDATE, Mie Mie (JP); Yoshiharu ONO, Yokkaichi Mie (JP); Jun TAKAGI, Yokkaichi Mie (JP); Kohei NAKAMURA, Yokkaichi Mie (JP); Tomohiko MINAMI, Yokkaichi Mie (JP)

(21) Appl. No.: 19/065,312

(22) Filed: Feb. 27, 2025

(30) Foreign Application Priority Data
Sep. 17, 2024 (JP) 2024-159730

(51) Int. Cl. B32B 43/00; H01L 21/68; H01L 21/683

(52) U.S. Cl. CPC B32B 43/006; H10P 72/50; H10P 72/78; B32B 2309/72

(57) ABSTRACT

According to some embodiments, provided is a separation system configured to separate a bonded substrate, in which a first substrate and a second substrate are bonded together, into the first substrate and the second substrate. The separation system includes a first chuck configured to hold the first substrate of the bonded substrate. The separation system includes a second chuck configured to hold the second substrate of the bonded substrate and move the second substrate in a first direction away from a plate surface of the first substrate. The separation system includes an adjuster configured to adjust a tilt of the second chuck with respect to a direction perpendicular to a set line set on a holding surface of the second substrate of the second chuck. The separation system includes a controller configured to operate the adjuster to maintain symmetrical progression of the separation relative to the set line.

### CROSS-REFERENCE TO RELATED APPLICATION

This application is based upon and claims the benefit of priority from Japanese Patent Application No. 2024-159730, filed Sep. 17, 2024, the entire contents of which are incorporated herein by reference.

### FIELD

Embodiments described herein relate generally to a separation system and a separation method.

### BACKGROUND

In the manufacturing process or the like of a semiconductor device, substrates may be bonded to each other. When the two substrates are bonded together with a misalignment, the two substrates may be separated from each other.

As a method for separating two substrates, a method is used in which separation progresses along a direction of propagation from one substrate to the other. At this time, when the separation progresses asymmetrically with respect to the propagation direction, a stress may concentrate at certain points, causing the substrate to crack.

### DESCRIPTION OF THE DRAWINGS

FIG. 1 is a schematic side view showing a configuration of a separation system according to Embodiment 1.

FIG. 2 is a schematic cross-sectional view of a bonded substrate according to Embodiment 1.

FIG. 3 is a schematic plan view of a second chuck according to Embodiment 1.

FIGS. 4A and 4B are views illustrating a progress state of separation with respect to a set line according to Embodiment 1.

FIGS. 5A and 5B are views illustrating a tilt adjustment process according to Embodiment 1.

FIG. 6 is a view sequentially illustrating a part of a procedure of a separation process using the separation system according to Embodiment 1.

FIG. 7 is a view sequentially illustrating a part of a procedure of a separation process using the separation system according to Embodiment 1.

FIG. 8 is a view sequentially illustrating a part of a procedure of a separation process using the separation system according to Embodiment 1.

FIG. 9 is a flowchart illustrating a flow of a tilt adjustment process according to Embodiment 1.

FIG. 10 is a view sequentially illustrating a part of a procedure of a separation process using the separation system according to Embodiment 1.

FIG. 11 is a view sequentially illustrating a part of a procedure of a separation process using the separation system according to Embodiment 1.

FIG. 12 is a schematic plan view of a chuck support portion according to Embodiment 2.

FIGS. 13A and 13B are views illustrating a tilt adjustment process according to Embodiment 2.

### DETAILED DESCRIPTION

Embodiments provide a separation system and a separation method capable of progressing with separation symmetrically with respect to a propagation direction.

In general, according to one embodiment, provided is a separation system configured to separate a bonded substrate, in which a first substrate and a second substrate are bonded together, into the first substrate and the second substrate, the separation system including: a first chuck configured to hold the first substrate of the bonded substrate; a second chuck configured to hold the second substrate of the bonded substrate and move the second substrate in a first direction away from a plate surface of the first substrate; an adjuster configured to adjust a tilt of the second chuck with respect to a direction perpendicular to a set line set on a holding surface of the second substrate of the second chuck; and a controller configured to operate the adjuster to maintain symmetrical progression of the separation relative to the set line.

Embodiments will be described in detail below with reference to the drawings. The present disclosure is not limited to the following embodiments. The components in the following embodiments include those that can be easily assumed by those skilled in the art or those that are substantially the same.

### Embodiment 1

Configuration Example of Separation system

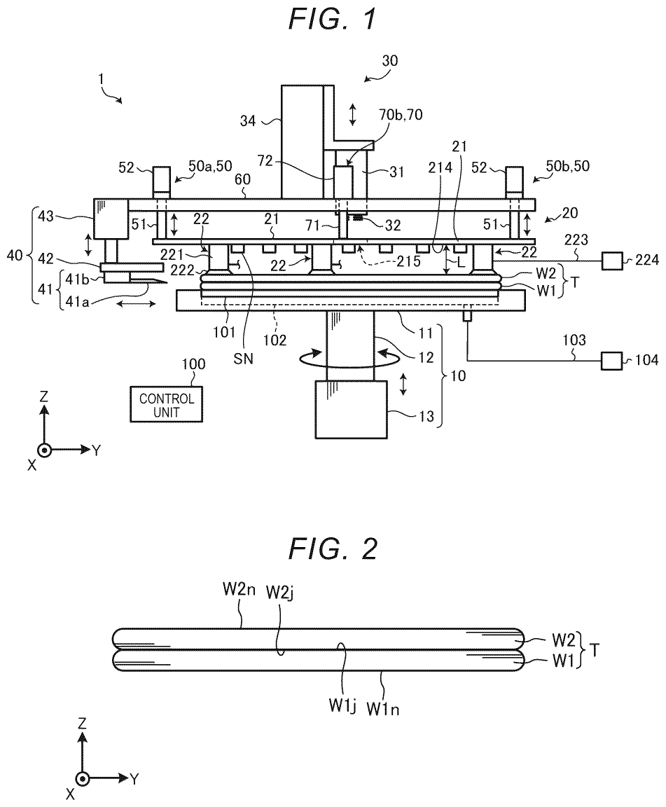

A separation system 1 according to Embodiment 1 will be described with reference to FIGS. 1 to 10.

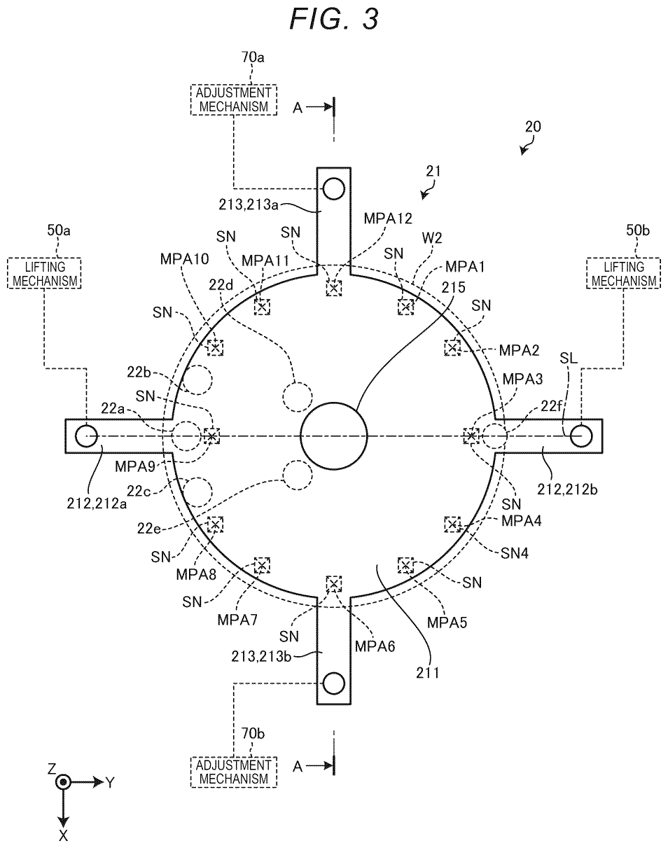

FIG. 1 is a schematic side view showing a configuration of a separation system 1 according to Embodiment 1. FIG. 2 is a schematic cross-sectional view of a bonded substrate T according to Embodiment 1. In FIG. 2, hatching is omitted for ease of viewing.

The separation system 1 shown in FIG. 1 is a device configured to execute a separation process to separate a bonded substrate T, in which a first substrate W1 and a second substrate W2 are bonded together, into the first substrate W1 and the second substrate W2, as shown in FIG. 2, for example.

In the present specification, the first substrate W1 is referred to as a “lower wafer W1” and the second substrate W2 is referred to as an “upper wafer W2” hereinafter. That is, the lower wafer W1 is an example of a first substrate, and the upper wafer W2 is an example of a second substrate.

In the present specification, as shown in FIG. 2, among the plate surfaces of the lower wafer W1, a plate surface that is bonded to the upper wafer W2 is referred to as a “bonding surface W1j”, and a plate surface opposite to the bonding surface W1j is referred to as a “non-bonding surface W1n”. Furthermore, among the plate surfaces of the upper wafer W2, a plate surface that is bonded to the lower wafer W1 is referred to as a “bonding surface W2j”, and a plate surface opposite to the bonding surface W2j is referred to as a “non-bonding surface W2n”. The lower wafer W1 and the upper wafer W2 may be bonded together, for example, chemically or by an adhesive.

In the present specification, a predetermined direction along the bonding surface of the bonded substrate T held in the separation system 1 is defined as a Y direction. The Y direction is also a direction along a line connecting the center of a main body portion 211 of an elastic member 21 to be described later and a separation inductor 40. A direction from the separation inductor 40 toward the center of the main body portion 211 is defined as the positive Y direction, and an opposite direction is defined as the negative Y direction. A vertical direction of the separation system 1 is defined as a Z direction. In this case, an upward direction is defined as the positive Z direction, and a downward direction is defined as the negative Z direction. The Y direction and the Z direction are perpendicular to each other. Moreover, a direction along the bonding surface of the bonded substrate T and intersecting with the Y and Z directions is defined as an X direction. At this time, the positive X direction and the negative X direction are defined such that when viewed from the positive Z direction side, that is, when viewing the separation system 1 downward, the positive X direction, the positive Y direction, the negative X direction, and the negative Y direction are arranged counterclockwise. The X direction is an example of a second direction, and the Z direction is an example of a first direction.

As shown in FIG. 1, the separation system 1 includes a first chuck 10, a second chuck 20, a holding portion 30, the separation inductor 40, a plurality of lifters 50 (also referred to here as “lifting mechanism 50” and/or “lifting systems 50”), a chuck support portion 60, a plurality of adjusters 70 (also referred to herein as “adjustment mechanisms 70” and/or “adjustment systems 70”), a sensor SN, and a controller 100. The controller 100 can be implemented as a processing circuit including at least one processor or memory. The sensor SN can be implemented as a processing circuit including at least one processor or memory.

The first chuck 10 is disposed at the lower part of the separation system 1 (also referred to herein as “separation apparatus 1”) and holds the lower wafer W1 of the bonded substrate T that has been carried into the separation system 1. Specifically, the first chuck 10 has a main body portion 11, a support member 12, and a rotary lifter 13.

The main body portion 11 is formed of a substantially circular metal member such as aluminum. A suction surface 101 is provided on the upper surface of the main body portion 11. The suction surface 101 has a diameter substantially equal to that of the lower wafer W1. The suction surface 101 is formed of a porous resin member such as polychlorotrifluoroethylene (PCTFE), for example. A suction space 102 that communicates with the outside via the suction surface 101 is formed inside the main body portion 11. The suction space 102 is connected to a suction device 104 such as a vacuum pump via a suction pipe 103.

The first chuck 10 uses a negative pressure generated by the suction of the suction device 104 to suck the non-bonding surface W2n of the lower wafer W1 onto the suction surface 101. Accordingly, the lower wafer W1 is held in the main body portion 11. Generally, the first chuck 10 can be a mechanical holding mechanism that use vacuum suction and tilt adjustments to grip and manipulate semiconductor wafers. That is, the first chuck 10 can secure wafers of varying diameters by adjusting the suction force applied through the suction surface 101. The suction surface 101, formed from a porous resin material such as polychlorotrifluoroethylene (PCTFE), provides uniform vacuum distribution to prevent localized stress concentrations. The first chuck 10 can also maintain wafer positioning by counteracting lateral forces during the separation process, ensuring that the lower wafer W1 remains stationary while the second wafer W2 is lifted. Additionally, the first chuck 10 can be integrated with a height adjustment mechanism to accommodate wafers of different thicknesses and facilitate alignment with the second chuck 20.

In addition, the first chuck 10 is supported by the support member 12 and the rotary lifter 13. The rotary lifter 13 rotates the main body portion 11 by rotating the support member 12 around a vertical axis. The rotary lifter 13 raises and lowers the main body portion 11 by moving the support member 12 in the vertical direction.

The second chuck 20 is disposed above the first chuck 10 and holds the upper wafer W2 of the bonded substrate T that has been carried into the separation system 1. The second chuck 20 has the elastic member 21 and a plurality of suction portions 22. Generally, the second chuck 20 can be a mechanical holding mechanism that use vacuum suction and tilt adjustments to grip and manipulate semiconductor wafers. That is, the second chuck 20 can apply a controlled suction force to the non-bonding surface W2n of the upper wafer W2 using the plurality of suction portions 22. The elastic member 21, which is a thin metal structure, allows for slight deformation to accommodate variations in wafer surface topology while maintaining uniform contact pressure. The second chuck 20 can move in the positive Z direction to separate the upper wafer W2 from the lower wafer W1. Additionally, the second chuck 20 can dynamically adjust its tilt using adjustment mechanisms 70a and 70b, ensuring that the separation progresses symmetrically relative to a predefined set line SL. This controlled movement prevents stress concentrations that could lead to wafer cracking during the separation process.

The elastic member 21 is formed of a thin metal member. The elastic member 21 is disposed above the upper wafer W2 and faces the upper wafer W2.

A plurality of suction portions 22 are disposed on the lower surface of the elastic member 21. Each suction portion 22 is connected to a suction device 224 such as a vacuum pump via a suction pipe 223. Specifically, the suction portion 22 has an elastic body 221 (also referred to herein as a “deformable support structure”)(e.g., a deformable structure, such as a rubber or polymer component, that expands and contracts to compensate for variations in surface contact pressure and distribute suction force uniformly across the wafer surface) fixed to the lower surface of the elastic member 21, and a suction pad 222 provided on the lower part of the elastic body 221.

The suction pad 222 is sucked to the non-bonding surface W2n of the upper wafer W2 by a suction force generated by the suction device 224. That is, the elastic member 21 holds the upper wafer W2 via the suction pad 222 and the elastic body 221.

The elastic body 221 is formed of a member such as a rubber. The elastic body 221 expands and contracts in response to a stress in the Z direction applied to the upper wafer W2 sucked by the suction pad 222.

The lifter 50 is connected to the elastic member 21. The upper wafer W2 held by the elastic member 21 is moved upward by the operation of the lifter 50. Accordingly, the separation of the lower wafer W1 and the upper wafer W2 progresses.

At this time, a stress is applied to the upper wafer W2 according to the degree of ease of separation from the lower wafer W1. For example, the more difficult it is for the separation to progress, the larger the downward stress applied to the upper wafer W2. The larger the downward stress applied to the upper wafer W2, the more the elastic body 221 stretches. The distance between the upper wafer W2 and the elastic member 21 varies depending on the amount of expansion and contraction of the elastic body 221.

The holding portion 30 is disposed above the second chuck 20, and receives the upper wafer W2 after separating from the second chuck 20 and holds the upper wafer W2. The holding portion 30 includes a main body portion 31, a plurality of suction pads 32, and a lifter 34.

The main body portion 31 is a cylindrical member, and is inserted into an opening 215 of the elastic member 21. A plurality of suction pads 32 are provided on the lower part of the main body portion 31. The plurality of suction pads 32 are configured to be able to hold the non-bonding surface W2n of the upper wafer W2. The lifter 34 moves the main body portion 31 in the vertical direction, thereby raising and lowering the plurality of suction pads 32. The lifter 34 is supported by, for example, the chuck support portion 60.

The chuck support portion 60 is a plate-shaped member extending in an XY direction, and is disposed above the second chuck 20. The chuck support portion 60 is supported by a fixing member (not shown) attached to the ceiling portion of the separation system 1.

The separation inductor 40 is disposed on the negative Y direction side with respect to the second chuck 20. The separation inductor 40 can be implemented as a processing circuit including at least one processor or memory. The separation inductor 40 forms a separation start portion on the side surface of the bonded substrate T, which serves as a trigger for separating the upper wafer W2 and the lower wafer W1 from each other. Specifically, the separation inductor 40 has a blade portion 41, a moving mechanism 42, and a lifter 43.

The blade portion 41 has a sharp member 41a and a support portion 41b. The sharp member 41a is, for example, a flat blade, and is supported by the support portion 41b such that the tip of the blade protrudes in a direction along the bonding surface of the bonded substrate T.

The separation inductor 40 adjusts the height position of the blade portion 41 using the lifter 43, and then moves the blade portion 41 in the horizontal direction using the moving mechanism 42. Furthermore, the separation inductor 40 brings the sharp member 41a of the blade portion 41 into contact with the bonding portion between the upper wafer W2 and the lower wafer W1 exposed on the side surface of the bonded substrate T. Accordingly, a separation start portion is formed on the side surface of the bonded substrate T on the negative Y direction side.

FIG. 3 is a schematic plan view of the second chuck 20 according to Embodiment 1. More specifically, FIG. 3 is a view of the second chuck 20 as seen from above.

As shown in FIG. 3, the elastic member 21 of the second chuck 20 has a main body portion 211, a plurality of (here, two) first extension portions 212, and a plurality of (here, two) second extension portions 213.

The main body portion 211 is a portion of the elastic member 21 that faces the upper wafer W2. The main body portion 211 is formed in a substantially circular shape having a diameter substantially equal to that of the upper wafer W2. An opening 215 for penetrating the holding portion 30 therethrough is formed near the center of the main body portion 211. Further, the above-described plurality of (here, six) suction portions 22 are disposed on a lower surface 214 of the main body portion 211. The lower surface 214 is an example of a holding surface.

Among the six suction portions 22, suction portions 22a to 22c are disposed on the edge of the outer periphery on the negative Y direction side of the lower surface 214 of the main body portion 211. Among these three, the suction portions 22b and 22c are disposed side by side along the X direction with the set line SL interposed therebetween. The suction portions 22d to 22e are disposed side by side along the X direction around the periphery of the opening 215 with the set line SL interposed therebetween. The suction portion 22f is disposed on the outer periphery of the lower surface 214 on the positive Y direction side. That is, the six suction portions 22 are disposed in the order of suction portions 22a to 22c, 22d to 22e, and 22f from the negative Y direction side to the positive Y direction side.

Furthermore, the suction portion 22a is adjacent to the separation start portion formed by the sharp member 41a of the blade portion 41. That is, the sharp member 41a forms a separation start portion in the vicinity of the suction portion 22a.

Although an example in which six suction portions 22 are provided on the main body portion 211 has been shown here, the number of suction portions 22 provided on the main body portion 211 is not limited to six.

The two first extension portions 212 are portions formed by partially extending the outer periphery of the main body portion 211 outward along the Y direction. Specifically, out of the two first extension portions 212, the first extension portion 212a is a portion of the outer periphery of the main body portion 211 on the negative Y direction side that extends toward the negative Y direction side. The other first extension portion 212b is a portion of the outer periphery of the main body portion 211 on the positive Y direction side that extends toward the positive Y direction side. A lifter 50a is connected to the tip of the first extension portion 212a, and a lifter 50b is connected to the tip of the first extension portion 212b. That is, the lifters 50a and 50b are arranged along the Y direction.

Each of the lifters 50a and 50b includes a support member 51 and a moving mechanism 52 (FIG. 1). The support member 51 is a portion that is connected to each of the first extension portions 212a and 212b. The moving mechanism 52 is fixed to the upper part of the chuck support portion 60 and raises and lowers the support member 51 connected to the lower part. Accordingly, the first extension portions 212a and 212b can be raised and lowered.

The lifters 50a and 50b execute the above-described operations in accordance with instructions from the controller 100. The lifters 50a and 50b can be mechanical actuators communicably coupled to the processing circuits of the controller 100. The lifters 50a and 50b can include a processing circuit (e.g., integrated sensors and/or control electronics) including at least one processor or memory. For example, when the lifter 50a executes the above-described operation, the first extension portion 212a is pulled upward, and in conjunction with this, the end portion of the main body portion 211 on the negative Y direction side is raised. As the negative Y direction side of the main body portion 211 is raised, the end portion of the upper wafer W2 held on the lower surface 214 of the main body portion 211 on the negative Y direction side is also pulled upward.

A separation start portion is formed on the side surface on the negative Y direction side of the bonded substrate T, and when the lifter 50a executes the above-described operation, separation starts from the negative Y direction side. Accordingly, the separation progresses along the line connecting the lifter 50a and the lifter 50b. Hereinafter, the line connecting the lifter 50a and the lifter 50b is referred to as a set line SL. The set line SL is also a line along the Y direction.

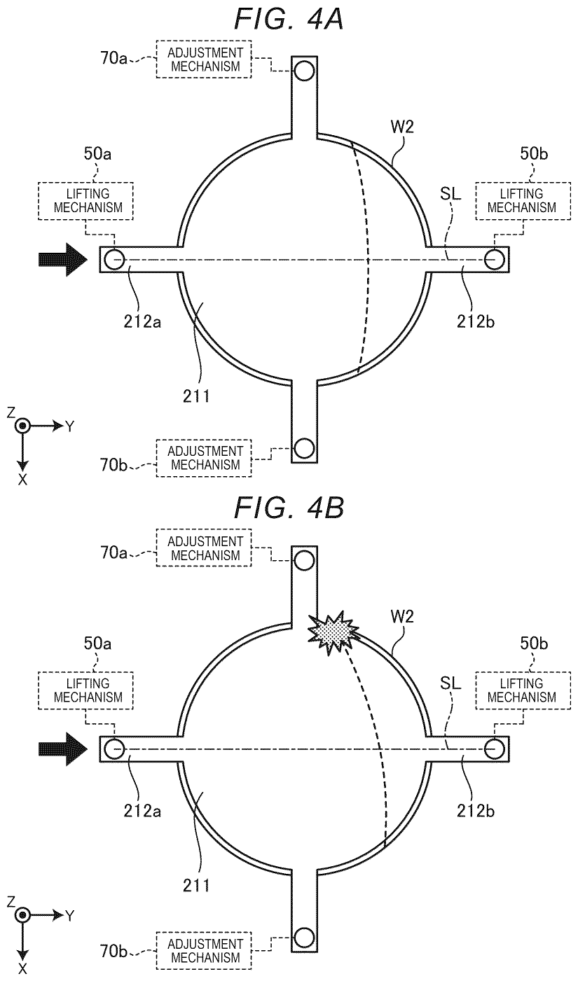

FIGS. 4A and 4B are views illustrating a progress state of separation with respect to the set line SL according to Embodiment 1.

FIGS. 4A and 4B are views of the second chuck 20 holding the upper wafer W2 as viewed from above. The arrows shown in FIGS. 4A and 4B indicate the direction in which separation progresses. The dashed lines shown in FIGS. 4A and 4B indicate the boundary lines between an area where the upper wafer W2 has been separated from the lower wafer W1 and an area where the upper wafer W2 has not been separated. That is, the side of the dashed line in the progressing direction is an area where the upper wafer W2 has not been separated, and the opposite side is an area where the upper wafer W2 has previously been separated.

Ideally, the separation of the upper wafer W2 progresses symmetrically with respect to the set line SL, as shown in FIG. 4A. However, in reality, as shown in FIG. 4B, the separation progresses asymmetrically with respect to the set line SL. For example, as in the example of FIG. 4B, when separation does not progress as much on the negative X-direction side as compared with the positive X direction side, a location where a stress is concentrated occurs on the negative X direction side, which may cause the substrate to crack.

The separation system 1 according to Embodiment 1 is provided with an adjuster 70 for adjusting the progress of separation in a direction (X direction) intersecting the set line SL. The adjuster 70 is connected to the tips of the two second extension portions 213.

Referring back to FIG. 3, two second extension portions 213 are portions formed by partially extending the outer periphery of the main body portion 211 outward along the X direction. More specifically, out of the two second extension portions 213, the second extension portion 213a is a portion of the outer periphery of the main body portion 211 on the negative X direction side that extends toward the negative X direction side. The other second extension portion 213b is a portion of the outer periphery of the main body portion 211 on the positive X direction side that extends toward the positive X direction side. An adjuster 70a and/or adjustment system 70a is connected to the tip of the second extension portion 213a, and an adjuster 70b is connected to the tip of the second extension portion 213b. That is, the adjusters 70a and 70b are arranged along the X direction.

Each of the adjusters 70a and 70b (adjuster 70) includes a support member 71 and a moving mechanism 72 (FIG. 1). The support member 71 is a portion that is connected to each of the second extension portions 213a and 213b. The moving mechanism 72 is fixed to the upper part of the chuck support portion 60 and raises and lowers the support member 71 connected to the lower part. Accordingly, the second extension portions 213a and 213b can be raised and lowered.

The adjusters 70a and 70b execute the above-described operations in accordance with instructions from the controller 100. Specifically, in response to an instruction from the controller 100, one of the two adjusters 70 executes the above-described operation.

For example, when the adjuster 70a executes the above-described operation, the second extension portion 213a is pulled upward, and in conjunction with this, the end portion of the main body portion 211 on the negative X direction side is raised. That is, the second chuck 20 is tilted with the negative X direction side facing up. As the negative X direction side of the second chuck 20 is raised (e.g., move a second substrate in a first direction away from a plate surface of the first substrate), the negative X direction side of the upper wafer W2 is also pulled upward. Accordingly, the separation of the upper wafer W2 can be progressed on the negative X direction side.

On the other hand, for example, when the adjuster 70b executes the above-described operation, the second extension portion 213b is pulled upward, and in conjunction with this, the outer periphery of the main body portion 211 on the positive X direction side is raised. That is, the second chuck 20 is tilted with the positive X direction side facing up. As the positive X direction side of the second chuck 20 is raised, the positive X direction side of the upper wafer W2 is also pulled upward. Accordingly, the separation of the upper wafer W2 can be progressed on the positive X direction side.

Further, a plurality of (here, 12) sensors SN are disposed on the lower surface 214 of the main body portion 211. The sensor SN is, for example, a distance measurement sensor. The sensor SN is disposed at a position overlapping with a plurality of measurement points MPA provided on the lower surface 214 of the main body portion 211, and measures a distance L (FIG. 1) between the lower surface 214 and the non-bonding surface W2n of the upper wafer W2 at each measurement point MPA. The sensor SN transmits a measurement result of the distance L to the controller 100.

As shown in FIG. 3, a plurality of (here, 12) measurement points MPA are provided circumferentially along the outer periphery of the lower surface 214 of the main body portion 211. The twelve measurement points MPA form a plurality of pairs with the set line SL interposed therebetween, and each pair of measurement points MPA are arranged along the X direction. That is, the pair of measurement points MPA are disposed at positions symmetrical to each other with respect to the set line SL interposed therebetween.

In the example shown in FIG. 3, for example, measurement points MPA8 and MPA10, measurement points MPA7 and MPA11, measurement points MPA6 and MPA12, measurement points MPA1 and MPA5, and measurement points MPA2 and MPA4 each form a pair. Moreover, these plurality of (here, five) pairs are disposed from the negative Y direction side to the positive Y direction side. The measurement points MPA1 to MPA12 are examples of a first point and a second point.

The controller 100 is configured as a computer including a central processing unit (CPU) (also referred to herein as “processor(s),” “processing circuits,” and/or “processing systems”), a read only memory (ROM), a random access memory (RAM), and the like (not shown), and controls the entire separation system 1. For example, the controller 100 controls the adjuster 70 based on the measurement result of the distance L acquired from the sensor SN. Hereinafter, the control process of the adjuster 70 by the controller 100 may be referred to as a tilt adjustment process.

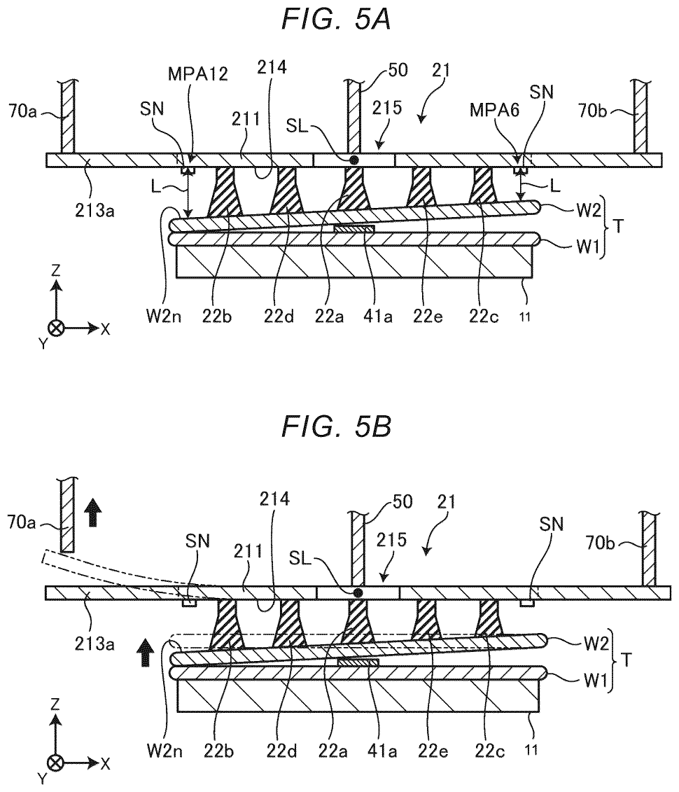

FIGS. 5A and 5B are views illustrating a tilt adjustment process according to Embodiment 1.

FIGS. 5A and 5B are schematic cross-sectional views of a part of the separation system 1 including a cross section along line AA in FIG. 3, which show a state in which the bonded substrate T is held. The front side of the paper surface indicates the negative Y direction side, and the back side of the paper surface indicates the positive Y direction side. For ease of description, in FIGS. 5A and 5B, components such as the suction portion 22 and the sharp member 41a that are not necessarily provided in the same cross section may be shown.

Specifically, when the controller 100 acquires the distance L at each measurement point MPA from the sensor SN, the controller 100 calculates a difference between the distances L at the pair of measurement points MPA. The controller 100 determines, based on the absolute value of the difference in the distance L, whether the separation of the upper wafer W2 is progressing symmetrically with respect to the set line SL.

As described above, the distance L varies depending on the amount of expansion and contraction of the suction portions 22a to 22f. The amount of expansion and contraction of the suction portions 22a to 22f varies depending on the degree to which separation between the lower wafer W1 and the upper wafer W2 progresses easily. Therefore, by obtaining the difference in the distance L between a pair of measurement points MPA provided at positions symmetrical to each other with respect to the set line SL interposed therebetween, it is possible to determine whether the separation is progressing symmetrically with respect to the set line SL.

More specifically, when the absolute value of the difference in the distance L between all pairs of a plurality of measurement points MPA is below a predetermined threshold, the controller 100 determines that the separation is progressing symmetrically with respect to the set line SL. On the other hand, when the absolute value of the difference in the distance L between at least one pair of a plurality of measurement points MPA exceeds a predetermined threshold, the controller 100 determines that the separation is not progressing symmetrically with respect to the set line SL.

Furthermore, the controller 100 determines whether the separation is progressing more on the positive X direction side or the negative X direction side with respect to the set line SL, based on the sign of the difference. For example, a case is considered in which the controller 100 calculates the difference by subtracting the value detected by the sensor SN provided on the negative X direction side from the value detected by the sensor SN provided on the positive X direction side. When the sign of the difference is positive, it is determined that the separation on the positive X direction side is not progressing. When the sign of the difference is negative, it is determined that the separation on the negative X direction side is not progressing.

For example, as shown in FIG. 5A, a case is assumed in which the distance L at the measurement point MPA12 provided on the negative X direction side of the set line SL interposed therebetween is greater than the distance L at the measurement point MPA6 provided on the positive X direction side. When the distance L at the measurement point MPA612 is subtracted from the distance L at the measurement point MPA6, the sign of the difference is negative. The controller 100 determines that the separation on the negative X direction side is not progressing as compared with the positive X direction side. The above-described determination based on the difference is just one example, and the present disclosure is not limited thereto.

The controller 100 controls the adjuster 70 according to the above-described determination result.

Specifically, when the controller 100 determines that the separation is not progressing symmetrically with respect to the set line SL, the controller 100 operates the adjuster 70 disposed on the side where the separation is not progressing, and tilts the second chuck 20.

For example, as shown in FIG. 5B, the controller 100 operates the adjuster 70a disposed on the negative X direction side to tilt the second chuck 20 such that the negative X direction side is at the top. Accordingly, the negative X direction side of the upper wafer W2 is pulled upward, and separation on the negative X direction side progresses.

On the other hand, for example, when the controller 100 determines that the separation is progressing symmetrically with respect to the set line SL, the controller 100 does not execute control of the adjusters 70a and 70b.

As described above, in the tilt adjustment process, the controller 100 controls the adjuster 70 based on the difference in the distance L, and adjusts the tilt of the second chuck 20 with respect to the X direction. Accordingly, the separation progresses symmetrically with respect to the set line SL. At this time, the controller 100 may adjust the angle of the second chuck 20 based on the magnitude of the difference in the distance L.

Here, the controller 100 determines the symmetry of the separation based on whether the difference in the distance L between at least one pair of a plurality of measurement points MPA exceeds a predetermined threshold, but the present disclosure is not limited thereto. For example, the controller 100 may determine that the separation is not progressing symmetrically with respect to the set line SL when the sum of the absolute values of the differences in distance L between the pairs of the plurality of measurement points MPA exceeds a predetermined threshold, and may determine that the separation is progressing symmetrically when the sum is below the predetermined threshold.

Furthermore, the controller 100 executes the above-described tilt adjustment process, for example, at predetermined time intervals from the start to the end of separation. The controller 100 can maintain symmetrical progression (e.g., ensure that the separation advances evenly on both sides of the set line to prevent stress concentration and substrate cracking) of the separation relative to the set line (e.g., a predefined axis along which the separation is intended to propagate, determined by the alignment of the lifters. Accordingly, it is possible to adjust the progress of separation in the direction intersecting the set line SL (X direction) in accordance with the progress of separation along the set line SL.

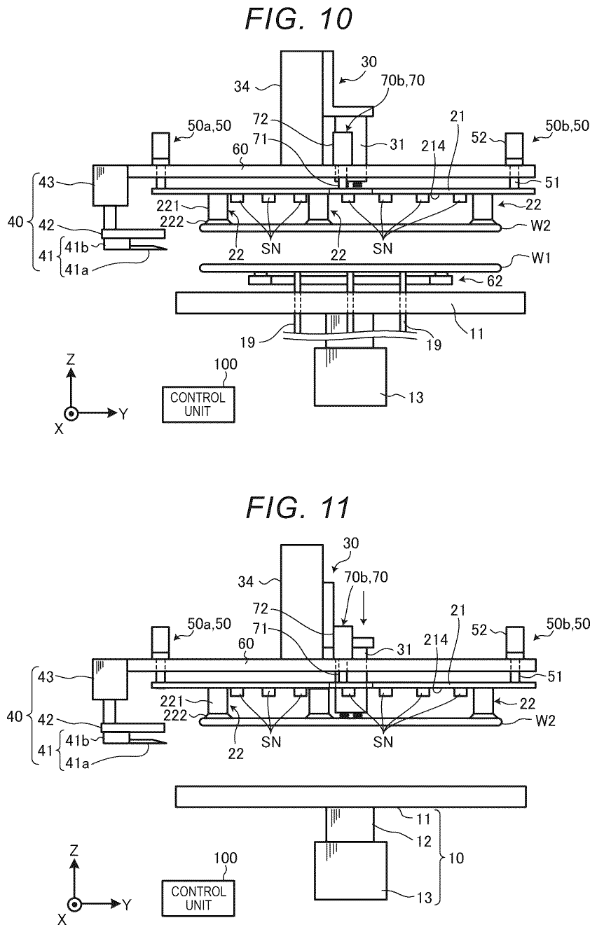

The separation system 1 further includes a plurality of lifting pins 19 (see FIG. 10) for supporting the bonded substrate T and the lower wafer W1 after separation. The plurality of lifting pins 19 are inserted into through holes (not shown) penetrating the first chuck 10, and are configured to be freely raised and lowered by a lifter (not shown). The plurality of lifting pins 19 are used to temporarily support the bonded substrate T and the lower wafer W1 when the bonded substrate T is carried in and when the lower wafer W1 is carried out after separation.

### Separation Method

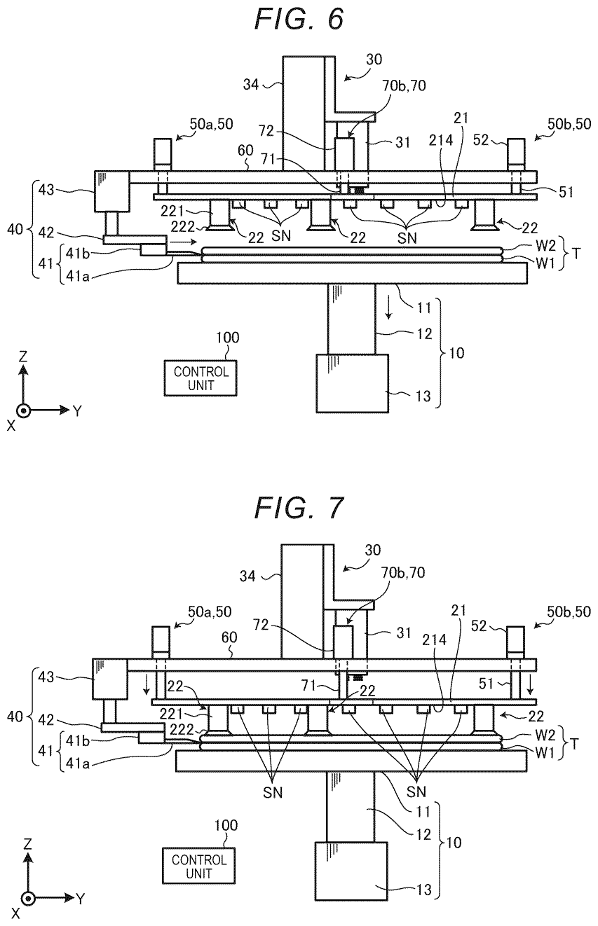

Next, a separation method of the bonded substrate T will be described with reference to FIGS. 6 to 11.

FIGS. 6 to 8 and 10 and 11 are views sequentially illustrating a part of a procedure of a separation process using the separation system 1 according to Embodiment 1. More specifically, FIGS. 6 to 8 and 10 and 11 are side views of the separation system 1 taken along the Y direction. FIG. 9 is a flowchart illustrating a flow of a tilt adjustment process according to Embodiment 1. The tilt adjustment process is performed as a part of the separation process.

First, in FIG. 6, when the bonded substrate T is carried into the separation system 1, the controller 100 places the bonded substrate T on the suction surface 101 and sucks the non-bonding surface W1n of the lower wafer W1 onto the suction surface 101. Accordingly, the lower wafer W1 is held. Next, the controller 100 moves the blade portion 41 in the positive Y direction, and presses the sharp member 41a against the side surface of the bonded substrate T on the negative Y direction side. Accordingly, a separation start portion is formed.

Next, in FIG. 7, the controller 100 lowers the suction pad 222 of the second chuck 20 to the vicinity of the upper wafer W2, and sucks the non-bonding surface W2n of the upper wafer W2. Accordingly, the upper wafer W2 is held.

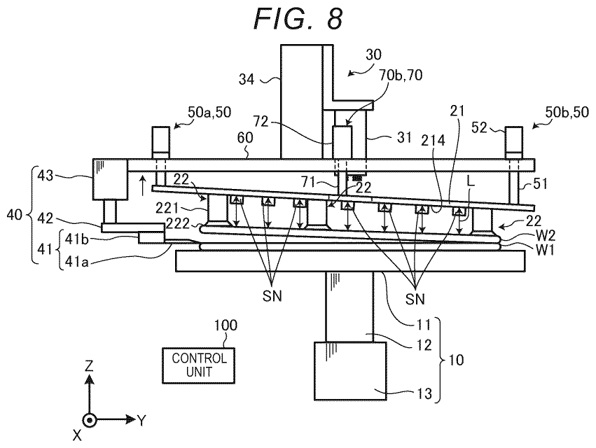

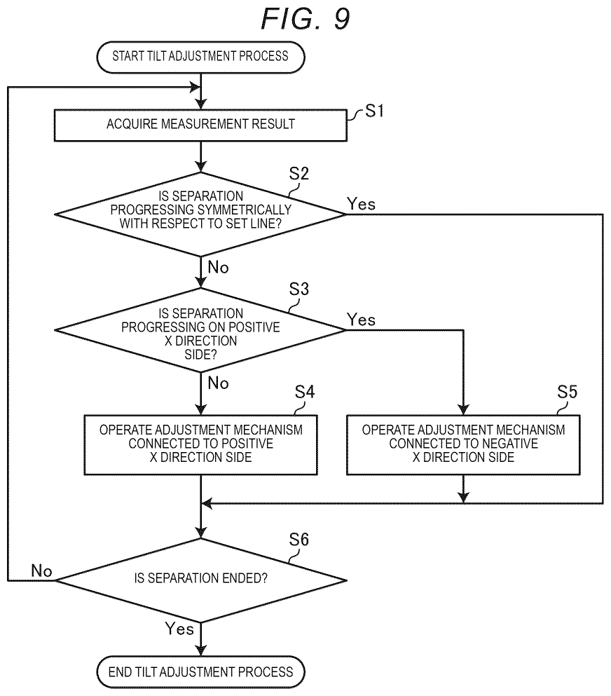

Next, in FIG. 8, the controller 100 controls the lifter 50a to pull the first extension portion 212a upward. Accordingly, the negative Y direction side of the main body portion 211 is pulled upward, and the upper wafer W2 starts to separate from the lower wafer W1 starting from the separation start portion. When separation starts, the sensor SN measures the distance L between the lower surface 214 and the non-bonding surface W2n of the upper wafer W2. The sensor SN transmits the distance L at each measurement point MPA to the controller 100 as a measurement result.

The controller 100 executes the tilt adjustment process. As shown in FIG. 9, the controller 100 acquires the measurement result of the distance L from the sensor SN (S1).

Next, the controller 100 determines whether the separation is progressing symmetrically with respect to the set line SL based on the measurement result (S2). Specifically, the controller 100 determines whether the separation is progressing symmetrically based on the absolute value of the difference in the distance L between the pair of measurement points MPA. When the controller 100 determines that the separation is progressing symmetrically (S2: Yes), the process proceeds to step S6.

When the controller 100 determines that the separation is not progressing symmetrically (S2: No), the controller 100 determines whether the separation is progressing on the positive X direction side (S3). Specifically, the controller 100 determines whether the separation is progressing more on the positive X direction side or the negative X direction side with respect to the set line SL, based on the sign of the difference.

When the controller 100 determines that separation is progressing on the positive X direction side (S3: Yes), the controller 100 operates the adjuster 70a connected to the negative X direction side to tilt the second chuck 20 such that the negative X direction side is at the top (S5). Accordingly, the separation on the negative X direction side progresses.

On the other hand, when the controller 100 does not determine that separation is progressing on the positive X direction side (S3: No), that is, when the controller 100 determines that separation is progressing on the negative X direction side, the controller 100 operates the adjuster 70b connected to the positive X direction side to tilt the second chuck 20 such that the positive X direction side is at the top (S4). Accordingly, the separation on the positive X direction side progresses.

The controller 100 determines whether separation of the upper wafer W2 is ended (S6). When the controller 100 determines that the separation is not ended (S6: No), the process returns to S1. When the controller 100 determines that the separation is ended (S6: Yes), the tilt adjustment process is ended.

In FIG. 10, the controller 100 raises the plurality of lifting pins 19 supporting the lower wafer W1 to the transfer position. Thereafter, the controller 100 carries the lower wafer W1 after the separation out of the separation system 1.

In FIG. 11, the controller 100 controls the lifter 34 to lower the suction pad 32 of the holding portion 30 to the vicinity of the upper wafer W2, and causes the suction pad 32 to suck the non-bonding surface W1n of the upper wafer W2. Next, the suction pad 222 of the second chuck 20 releases the upper wafer W2 from its suction. Accordingly, the upper wafer W2 is held by the suction pad 32 of the holding portion 30. Next, the controller 100 carries the upper wafer W2 after the separation out of the separation system 1. With the above, the separation process according to Embodiment 1 is ended.

### SUMMARY

The separation system 1 according to Embodiment 1 includes a first chuck 10 configured to hold (e.g., that holds) a lower wafer W1, a second chuck 20 configured to hold (e.g., that holds) an upper wafer W2 and move it upward, an adjuster 70 that can adjust the tilt of the second chuck 20 with respect to a direction perpendicular to a set line SL set on the second chuck 20, and a controller 100. The controller 100 controls the adjuster 70 such that the progress of separation is symmetrical with respect to the set line SL.

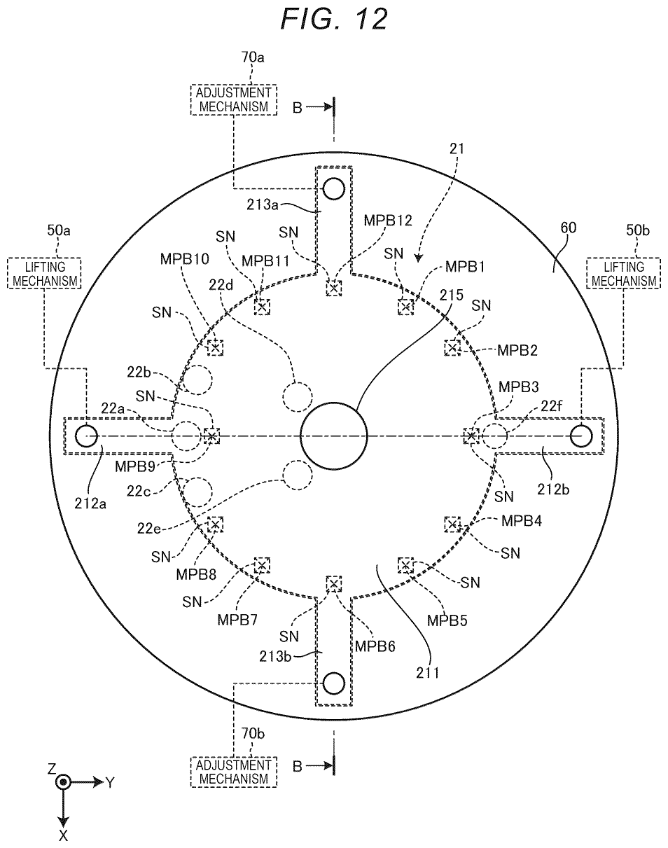

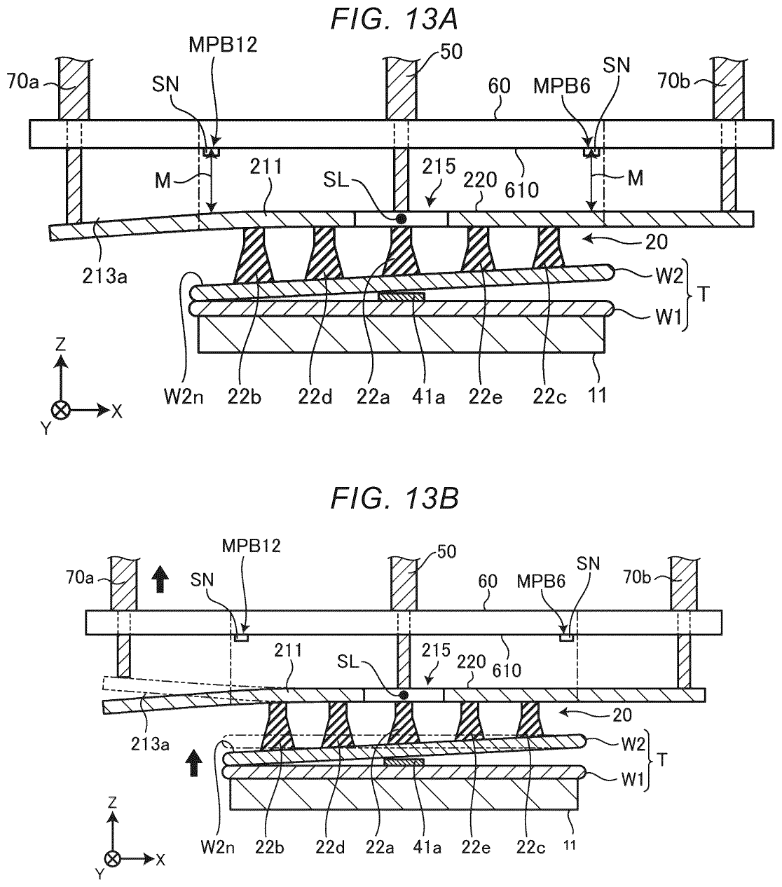

In this way, for example, the adjuster 70 can tilt the second chuck 20 such that the side where separation has not progressed is at the top relative to the set line SL, thereby moving the side of the upper wafer W2 where separation has not progressed upward. Accordingly, the separation on the side where the separation has not progressed can be caused to progress. As a result, the separation can progress symmetrically with respect to the set line SL, making it possible to reduce cracks in the substrate.

[Embodiment 2] A separation system according to Embodiment 2 will be described with reference to FIGS. 12 to 13B.

FIG. 12 is a schematic plan view of a chuck support portion 60 according to Embodiment 2. More specifically, FIG. 12 is a view of the chuck support portion 60 as viewed from above. FIGS. 13A and 13B are views illustrating a tilt adjustment process according to Embodiment 2. More specifically, FIGS. 13A and 13B are schematic cross-sectional views of a part of the separation system including a cross section along line BB in FIG. 12, with the front side of the paper surface indicating the negative Y direction side and the back side of the paper surface indicating the positive Y direction side.

In Embodiment 1 described above, the separation system 1 determines the symmetry of the progress of separation with respect to the set line SL based on the distance L between the lower surface 214 of the elastic member 21 and the non-bonding surface W2n of the upper wafer W2. In contrast, the separation system according to Embodiment 2 determines the symmetry of the progress of separation with respect to the set line SL based on a distance M between an upper surface 220 of the elastic member 21 and a lower surface 610 of the chuck support portion 60. In the following description, the same components as those in Embodiment 1 are denoted by the same reference numerals, and the description thereof may be omitted.

As described with reference to FIG. 1, above the second chuck 20, the chuck support portion 60 that supports the second chuck 20 is provided. The chuck support portion 60 is a plate-shaped member extending in the XY direction. That is, the chuck support portion 60 has a surface facing the elastic member 21.

As shown in FIGS. 12, 13A, and 13B, a plurality of measurement points MPB (here, 12 points) (e.g., discrete locations on the lower surface 610 of the chuck support portion 60 where sensors are positioned to measure the distance between the chuck support portion 60 and the upper surface 220 of the main body portion 211, providing real-time and/or near real-time data on deflection, tilt, and/or asymmetry in the separation process) are provided circumferentially on the outer periphery of the lower surface 610 of the chuck support portion 60 at a position overlapping with the main body portion 211. The twelve measurement points MPB form a plurality of pairs with the set line SL interposed therebetween, and each pair of measurement points MPB are arranged along the X direction.

In the example shown in FIG. 12, for example, measurement points MPB8 and MPB10, measurement points MPB7 and MPB11, measurement points MPB6 and MPB12, measurement points MPB1 and MPB5, and measurement points MPB2 and MPB4 each form a pair. The measurement points MPB1 to MPB12 are examples of a first point and a second point.

A sensor SN is disposed at a position overlapping with the measurement points MPB1 to MPB12. The sensor SN measures the distance M (FIGS. 13A and 13B) between the lower surface 610 of the chuck support portion 60 and the upper surface 220 of the main body portion 211 at each of the measurement points MPB1 to MPB12. The sensor SN transmits a measurement result of the distance M to the controller 100.

When the controller 100 acquires the distance M at each measurement point MPB from the sensor SN, the controller 100 calculates a difference between the distances M at the pair of measurement points MPB. The controller 100 determines, based on the absolute value of the difference in the distance M, whether the separation of the upper wafer W2 is progressing symmetrically with respect to the set line SL.

As described above, the elastic member 21 is formed of a thin metal member. Therefore, the elastic member 21 may bend downward in response to the stress in the Z direction applied to the upper wafer W2. When the main body portion 211 is bent downward, the distance M between the upper surface 220 of the main body portion 211 and the lower surface 610 of the chuck support portion 60 varies depending on the amount of bending. As described above, the stress in the Z direction applied to the upper wafer W2 is based on the degree of ease of separation from the lower wafer W1. Therefore, by obtaining the difference in the distance M between a pair of measurement points MPB provided at positions symmetrical to each other with respect to the set line SL interposed therebetween, it is possible to determine whether the separation is progressing symmetrically with respect to the set line SL.

Furthermore, the controller 100 determines whether the separation is progressing more on the positive X direction side or the negative X direction side with respect to the set line SL, based on the sign of the difference.

For example, as shown in FIG. 13A, a case is assumed in which the distance M at the measurement point MPB12 provided on the negative X direction side of the set line SL interposed therebetween is greater than the distance M at the measurement point MPB6 provided on the positive X direction side by a predetermined threshold. When the distance M at the measurement point MPB12 is subtracted from the distance M at the measurement point MPB6, the sign of the difference is negative. The controller 100 determines that the separation on the negative X direction side is not progressing as compared with the positive X direction side.

The controller 100 controls the adjuster 70 according to the above-described determination result.

Specifically, for example, as shown in FIG. 13B, the controller 100 operates the adjuster 70a to tilt the second chuck 20 such that the negative X direction side is at the top. Accordingly, the negative X direction side of the upper wafer W2 is pulled upward, and separation on the negative X direction side progresses. With the separation system and the separation method according to Embodiment 2, other effects similar to those of the above-described embodiments are achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A separation system configured to separate a bonded substrate, in which a first substrate and a second substrate are bonded together, into the first substrate and the second substrate, the separation system comprising:
a first chuck configured to hold the first substrate of the bonded substrate;
a second chuck configured to hold the second substrate of the bonded substrate and move the second substrate in a first direction away from a plate surface of the first substrate;
an adjuster configured to adjust a tilt of the second chuck with respect to a direction perpendicular to a set line set on a holding surface of the second substrate of the second chuck; and
a controller configured to operate the adjuster to maintain symmetrical progression of a separation relative to the set line.

2. The separation system of claim 1, wherein:
the second chuck is disposed on the holding surface of the second substrate and holds the second substrate via an elastic body that is expandable and contractible in response to a stress of the second substrate in the first direction;
a sensor is provided at each of a plurality of first points on the holding surface to measure a distance between the holding surface and the second substrate; and
the controller determines whether the progression of the separation is symmetrical with respect to the set line based on the distance measured by the sensor provided at each of the plurality of first points.

3. The separation system of claim 2, wherein:
the adjuster is connected to each of both end portions of the second chuck in a direction intersecting the set line; and
the plurality of first points are set on the holding surface inward from the both end portions.

4. The separation system of claim 2, wherein:
the plurality of first points comprise at least two second points arranged in a second direction intersecting the set line; and
the controller determines whether the progression of the separation is symmetrical with respect to the set line based on a difference in the distance between the at least two second points.

5. The separation system of claim 2, wherein the plurality of first points are set circumferentially on an end portion of the holding surface.

6. The separation system of claim 1, further comprising:
a chuck support portion that supports the second chuck from the first direction; and
a sensor is provided at each of a plurality of first points on a facing surface of the chuck support portion that faces the second chuck to measure a distance between the facing surface and the second chuck;
wherein the controller determines whether the progression of the separation is symmetrical with respect to the set line based on the distance measured by the sensor provided at each of the plurality of first points.

7. The separation system of claim 1, further comprising:
two lifters connected to the second chuck and configured to raise and lower the second chuck in the first direction;
wherein the set line is a line connecting positions of the second chuck where the two lifters are connected.

8. The separation system of claim 1, wherein the adjuster is connected to each of both end portions of the second chuck in a direction intersecting the set line.

9. A separation method executed by a separation system configured to separate a bonded substrate, in which a first substrate and a second substrate are bonded together, into the first substrate and the second substrate, the separation method comprising:
holding the first substrate of the bonded substrate in a first chuck;
holding the second substrate in a second chuck configured to move the second substrate in a first direction away from a plate surface of the first substrate; and
adjusting a tilt of the second chuck with respect to a direction perpendicular to a set line set on a holding surface of the second substrate of the second chuck to maintain symmetrical progression of a separation relative to the set line.

10. The method of claim 9, further comprising:
holding the second substrate via an elastic body that is expandable and contractible in response to a stress of the second substrate in the first direction.

11. The method of claim 9, further comprising:
measuring, at each of a plurality of first points, a distance between the holding surface and the second substrate.

12. The method of claim 11, wherein the plurality of first points comprise at least two second points arranged in a second direction intersecting the set line.

13. The method of claim 11, wherein the plurality of first points are set circumferentially on an end portion of the holding surface.

14. The method of claim 9, further comprising:
determining whether the progression of the separation is symmetrical with respect to the set line based on the distance measured by the sensor provided at each of the plurality of first points.

15. The method of claim 14, wherein:
determining whether the progression of the separation is symmetrical with respect to the set line is based on a difference in the distance between the at least two second points.
